(19) United States
(12) Patent Application Publication
(10) Pub. No.: US 2015/0145076 A1
(43) Pub. Date: May 28, 2015

(54) SEMICONDUCTOR PACKAGE AND MANUFACTURING METHOD THEREOF

(71) Applicant: SAMSUNG ELECTRO-MECHANICS CO., LTD., Suwon (KR)

(72) Inventors: Tae Hyun KIM, Suwon (KR); Heung Woo PARK, Suwon (KR); Sun Ho KIM, Suwon (KR)

(73) Assignee: SAMSUNG ELECTRO-MECHANICS CO., LTD., Suwon (KR)

(21) Appl. No.: 14/171,387

(22) Filed: Feb. 3, 2014

(30) Foreign Application Priority Data
Nov. 26, 2013 (KR) 10-2013-0144916

(51) Int. Cl. B81B 7/00; B81C 1/00

(52) U.S. Cl. CPC B81B 7/0077; B81C 1/00301; B81C 1/00333; B81B 7/007; B81B 2201/0228
USPC 257/415; 438/51

(57) ABSTRACT

There is provided a semiconductor package including: an application specific integrated circuit (ASIC) chip including a first bump ball and a second bump ball formed inwardly of the first bump ball; a micro electro mechanical system (MEMS) sensor electrically connected to the second bump ball; a lead frame electrically connected to the first bump ball and including a through hole formed therein; and a molded part covering the ASIC chip, the MEMS sensor, and the lead frame, wherein the ASIC chip is disposed above the lead frame.

### CROSS-REFERENCE TO RELATED APPLICATION

This application claims the benefit of Korean Patent Application No. 10-2013-0144916 filed on Nov. 26, 2013, with the Korean Intellectual Property Office, the disclosure of which is incorporated herein by reference.

### BACKGROUND

The present disclosure relates to a semiconductor package and a manufacturing method thereof.

Generally, inertial sensors, measuring acceleration and/or angular velocity, have been widely used in motion remote controls for screen conversion of mobile phones, games, digital televisions, game machine controllers, as well as sensor modules for sensing hand shake and sensing a position and an angle of motion, or the like.

In addition, inertial sensors sense motion as well as acceleration or angular velocity and convert the sensed information into electrical signals. Therefore, when a device is operated with a user's motion as an input, it is possible to implement a motion interface. In addition, the inertial sensor as described above has been widely used in the navigation devices and control sensors of airplanes and other vehicles, in addition to motion sensors provided in devices such as home appliances, or the like.

Further, as inertial sensors have been commonly used in portable electronic devices such as portable personal digital assistants (PDA), digital cameras, mobile phones, or the like, a technology allowing for the implementation of a compact and light inertial sensor with various functions has been required, such that a micro-sensor module should be developed.

Generally, a sensor module has a structure in which an application specific integrated circuit (ASIC) chip is bonded to a micro electro mechanical system (MEMS) sensor using an epoxy or die attach film (DAF) and the ASIC chip and the MEMS sensor are connected to a board by a bonding wire.

In the case of the sensor module as described above, a process for the bonding wire is added, and there is a limitation in miniaturizing a semiconductor package due to a space occupied by a pad for being connected to the bonding wire, or the like.

### SUMMARY

An aspect of the present disclosure may provide a semiconductor package capable of decreasing a total size of the semiconductor package and simplifying a manufacturing process, and a manufacturing method thereof.

According to an aspect of the present disclosure, a semiconductor package may include: an application specific integrated circuit (ASIC) chip including a first bump ball and a second bump ball formed inwardly of the first bump ball; a micro electro mechanical system (MEMS) sensor electrically connected to the second bump ball; a lead frame electrically connected to the first bump ball and including a through hole formed therein; and a molded part covering the ASIC chip, the MEMS sensor, and the lead frame, wherein the ASIC chip is disposed above the lead frame.

The ASIC chip may have a size larger than that of the MEMS sensor.

The second bump ball may be formed on one surface of the ASIC chip facing one surface of the MEMS sensor.

The first bump ball may be formed on a portion of one surface of the ASIC chip protruding outwardly of the MEMS sensor.

The MEMS sensor may be received in the through hole of the lead frame.

The through hole may have a size larger than that of the MEMS sensor and smaller than that of the ASIC chip.

Upper surfaces of the ASIC chip and the molded part may be positioned on the same plane.

An upper surface of the ASIC chip may be exposed to the outside of the molded part.

The through hole of the lead frame may include an extension portion formed to have a diameter larger than that of the through hole.

The molded part may be formed of any one of a silicone gel, an epoxy molding compound (EMC), and polyimide.

According to another aspect of the present disclosure, a manufacturing method of a semiconductor package, the manufacturing method may include: forming a first bump ball and a second bump ball positioned inwardly of the first bump ball on an ASIC chip; bonding a MEMS sensor to the ASIC chip; providing a lead frame including a through hole formed therein; bonding the ASIC chip and the lead frame to each other; and forming a molded part so as to cover the ASIC chip, the MEMS sensor, and the lead frame.

In the bonding of the ASIC chip and the lead frame, the MEMS sensor may be received in the through hole.

The providing of the lead frame including the through hole formed therein may include forming an extension portion in the through hole so as to have a diameter larger than that of the through hole.

In the forming of the molded part, an upper surface of the ASIC chip may be exposed to the outside of the molded part.

In the forming of the molded part, upper surfaces of the ASIC chip and the molded part may be positioned on the same plane.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a semiconductor package according to an exemplary embodiment of the present disclosure; and

FIGS. 2A through 2D are process flow charts showing a manufacturing method of a semiconductor package according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

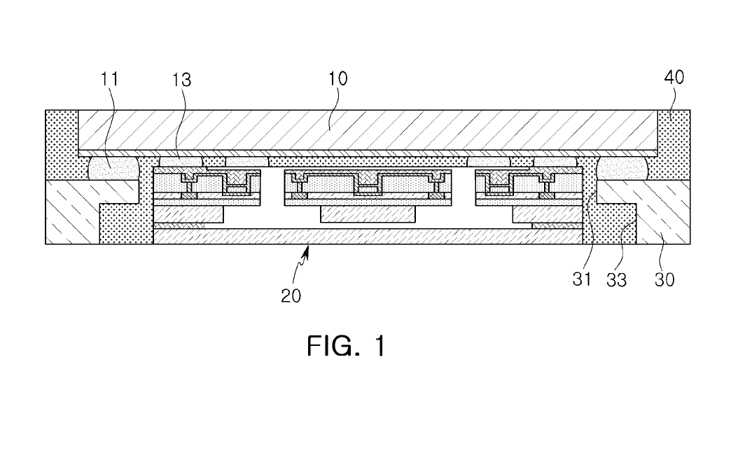

FIG. 1 is a cross-sectional view of a semiconductor package according to an exemplary embodiment of the present disclosure.

Referring to FIG. 1, the semiconductor package according to an exemplary embodiment of the present disclosure may include a lead frame 30, an ASIC chip 10, a MEMS sensor 20, and a molded part 40.

The ASIC chip 10 may be an application specific integrated circuit chip and be a chip in which a circuit receiving a signal from the MEMS sensor 20 to convert the received signal into an electric signal is integrated.

In addition, the ASIC chip 10 may serve to receive a signal generated in the MEMS sensor 20 to amplify the signal.

The ASIC chip 10 may be formed to have a size larger than that of the MEMS sensor 20. Therefore, in the case of bonding the ASIC chip 10 and the MEMS sensor 20 to each other, a portion protruding outwardly of the MEMS sensor 20 may be present in the ASIC chip 10.

First and second bump balls 11 and 13 may be formed on one surface of the ASIC chip, wherein the second bump ball 13 may be formed inwardly of the first bump ball 11.

In detail, the second bump ball 13 may be formed on one surface of the ASIC chip 10 facing one surface of the MEMS sensor 20.

In addition, the first bump ball 11 may be formed on the portion of one surface of the ASIC chip 10 protruding outwardly of the MEMS sensor 20.

The MEMS sensor 20 may mean an inertial sensor using a micromachining technology applying a semiconductor process called a micro electromechanical system (MEMS), particularly, an integrated circuit technology.

The MEMS sensor 20 may be bonded to the ASIC chip 10.

For example, the MEMS sensor 20 may be electrically connected to the second bump ball 13 provided on the ASIC chip 10.

Therefore, the ASIC chip 10 and the MEMS sensor 20 may be electrically connected to each other.

Here, the size of the MEMS sensor 20 may be smaller than that of the ASIC chip 10, such that the ASIC chip 10 may protrude outwardly of the MEMS sensor 20.

The lead frame 30 may serve as a wire connecting a semiconductor chip and an external circuit to each other and fix the semiconductor package to an electronic circuit board.

The lead frame 30 may be formed of a metal. For example, the lead frame 30 may be formed of nickel, an iron alloy, or a copper alloy. However, the lead frame 30 of the present disclosure is not limited thereto.

Mounting electrodes for mounting the ASIC chip 10 or circuit patterns (not shown) electrically interconnecting the mounting electrodes may be formed on the lead frame 30.

The ASIC chip 10 may be electrically connected to the lead frame 30 through flip chip bonding.

The lead frame 30 may be electrically connected to the first bump ball 11, thereby being electrically connected to the ASIC chip 10.

Therefore, the ASIC chip 10 may be disposed above the lead frame 30.

A through hole 31 penetrating through the lead frame 30 may be formed in the lead frame 30.

The MEMS sensor 20 may be inserted into the through hole 31.

In addition, the ASIC chip 10 attached onto the MEMS sensor 20 may be disposed above the lead frame 30.

In other words, the ASIC chip 10 may be disposed above the lead frame 30, and the MEMS sensor 20 may be received in the through hole 31 formed in the lead frame 30.

Here, the size of the MEMS sensor 20 may be smaller than that of the ASIC chip 10, such that a portion extended outwardly of the MEMS sensor 20 may be present in the ASIC chip 10.

Therefore, in the case in which the MEMS sensor 20 is received in the through hole 31, the first bump ball 11 may be formed on the portion of the ASIC chip 10 protruding outwardly of the MEMS sensor 20, such that the first bump ball 11 may be connected to the lead frame 30.

That is, since the MEMS sensor 20 having a size smaller than that of the ASIC chip 10 may be connected to the second bump ball 13 formed inwardly of the first bump ball 11, and the lead frame 30 may be connected to the first bump ball 11 formed outwardly of the second bump ball 13, the MEMS sensor 20 may be received in the through hole 31 formed in the lead frame 30.

Since the MEMS sensor 20 may be received in the through hole 31 formed in the lead frame 30, a separate thickness for mounting the MEMS sensor 20 may not be required.

As a result, a thickness of the semiconductor package according to an exemplary embodiment of the present disclosure may be determined depending on thicknesses of the MEMS sensor 20 and the ASIC chip 10, and the semiconductor package according to an exemplary embodiment of the present disclosure may be miniaturized by adjusting sizes of the MEMS sensor 20 and the ASIC chip 10.

Generally, in the case of a structure in which an ASIC chip is bonded to a MEMS sensor using an epoxy or die attach film (DAF) and the MEMS sensor and the ASIC chip are connected to a board by a bonding wire, there may be limitations in miniaturizing a semiconductor package due to a configuration such as pad for being connected to the bonding wire, or the like.

However, in the semiconductor package according to an exemplary embodiment of the present disclosure, since the MEMS sensor 20 and the ASIC chip 10 may be electrically connected by the second bump ball 13 and a separate bonding wire process is not required, a manufacturing process may be simplified, and the semiconductor package may be miniaturized.

In addition, the MEMS sensor 20 may be disposed so as to be received in the through hole 31 formed in the lead frame 30, such that the thickness of the semiconductor package may be decreased while using the existing MEMS sensor.

Meanwhile, the through hole 31 may be formed to have a size sufficient for the MEMS sensor 20 may be received therein. In detail, the through hole 31 may be formed to be larger than that of the MEMS sensor 20 and smaller than that of the ASIC chip 10.

An extension portion 33 having a diameter larger than that of the through hole 31 may be formed in the through hole 31 of the lead frame 30.

Therefore, the through hole 31 may be divided into a large diameter portion corresponding to a portion at which the extension portion 33 is formed and a small diameter portion corresponding to a portion at which the extension portion 33 is not formed, wherein a diameter of the large diameter portion corresponding to the portion at which the extension portion 33 is formed may be smaller than that of the small diameter portion corresponding to the portion at which the extension portion 33 is not formed.

The molded part 40 may be filled between the ASIC chip 10, the MEMS sensor 20 and the lead frame 30, such that the molded part 40 may prevent an electric short-circuit between the ASIC chip 10, the MEMS sensor 20 and the lead frame 30 and fix the ASIC chip 10, the MEMS sensor 20 and the lead frame 30 in a shape in which the molded part 40 encloses the ASIC chip 10, the MEMS sensor 20 and the lead frame 30, thereby safely protecting the semiconductor package according to an exemplary embodiment of the present disclosure from external impact.

In detail, the molded part 40 may cover the ASIC chip 10, the MEMS sensor 20 and the lead frame 30.

The molded part 40 may be formed in a shape in which the mold frame seals the ASIC chip 10, the MEMS sensor 20 and the lead frame 30 while covering them, such that the molded part 40 may protect the ASIC chip 10, the MEMS sensor 20 and the lead frame 30 from an external environment.

The molded part 40 may be formed by a molding method. In this case, at least one of a silicone gel having high thermal conductivity, an epoxy mold compound (EMC), polyimide may be used as a material of the molded part 40.

However, the present disclosure is not limited thereto, but in order to form the molded part, if necessary, various methods such as a method of compressing semi-cured resin, or the like, may be used.

The molded part 40 may be filled in the extension portion 33 formed in the lead frame 30, thereby improving impact resistance performance of the semiconductor package according to an exemplary embodiment of the present disclosure.

That is, a portion having a different diameter may be formed in the through hole 31 by the extension portion 33 (that is, a step structure), such that the molded part 40 filled in the extension portion 33 may function as a stopper so that the ASIC chip 10 and the MEMS sensor 20 are not separated from the lead frame 30 by external impacts, or the like.

Therefore, the semiconductor package according to an exemplary embodiment of the present disclosure may secure reliability against external impact, or the like.

Here, an upper surface of the molded part 40 and an upper surface of the ASIC chip 10 may be positioned on the same plane.

Therefore, the upper surface of the ASIC chip 10 may be exposed to the outside of the molded part 40.

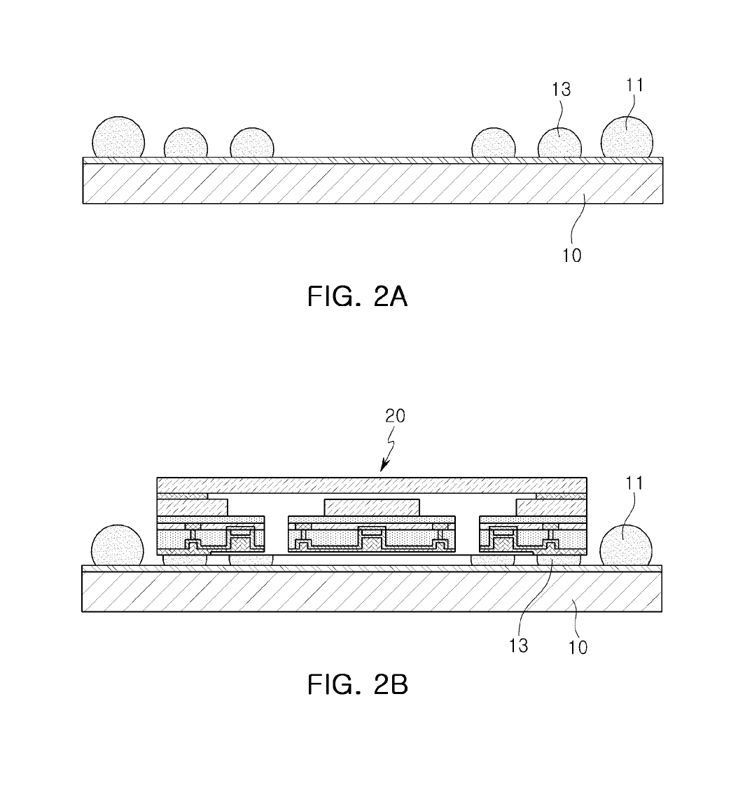

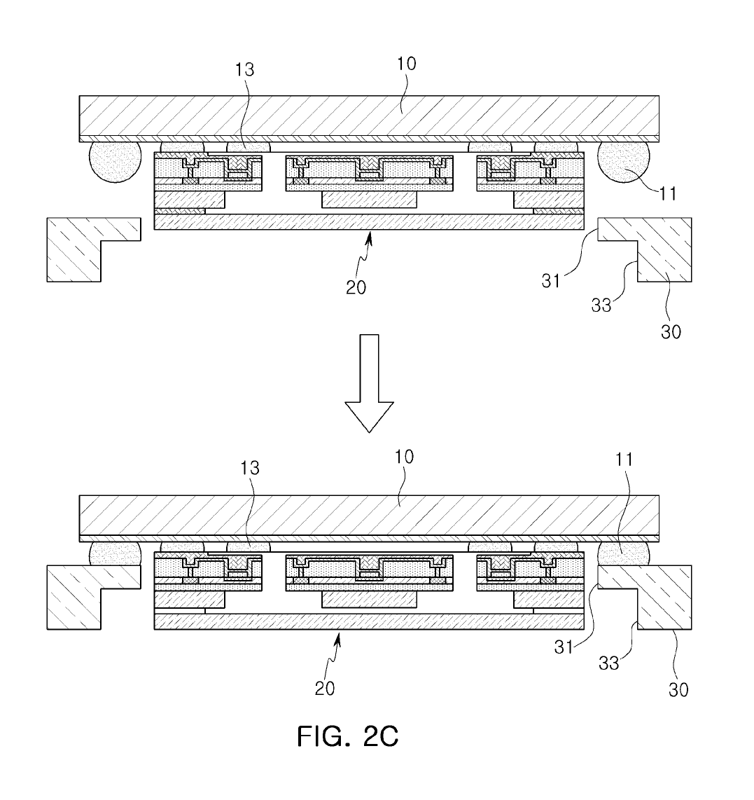

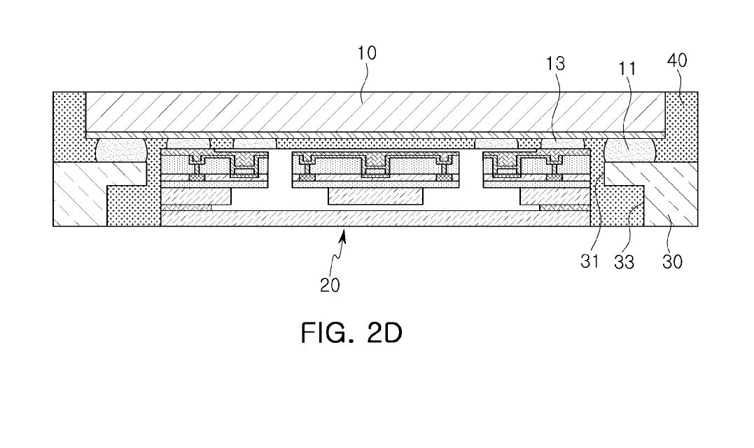

FIGS. 2A through 2D are process flow charts showing a manufacturing method of a semiconductor package according to an exemplary embodiment of the present disclosure.

The manufacturing method of a semiconductor package according to an exemplary embodiment of the present disclosure will be described with reference to FIGS. 2A through 2D.

First, first and second bump balls 11 and 13 may be formed on an ASIC chip 10.

The second bump ball 13 may be formed so as to be provided inwardly of the first bump ball 11.

In this exemplary embodiment, although the case in which the first and second bump balls 11 and 13 are formed on the ASIC chip 10 is described, the present disclosure is not limited thereto, but the second bump ball 13 may be formed on a MEMS sensor 20 and the first bump ball 11 may be formed on a lead frame 30.

Then, the MEMS sensor 20 may be bonded to the ASIC chip 10. In this case, the MEMS sensor 20 may have a size smaller than that of the ASIC chip 10 and be connected to the second bump ball 13 formed on the ASIC chip 10, such that the MEMS sensor 20 and the ASIC chip 10 may be electrically connected to each other.

In this case, a vacuum soldering or reflow soldering process may be used.

Next, mounting electrodes for mounting the ASIC chip 10 on the lead frame 30 or circuit patterns (not shown) electrically interconnecting the mounting electrodes may be formed, and a through hole 31 penetrating through the lead frame 30 may be formed.

Further, an extension portion 33 having a diameter larger than that of the through hole 31 may be formed in the through hole 31.

Therefore, the through hole 31 may be formed so that a diameter of a large diameter portion corresponding to a portion in which the extension portion 33 is formed may be larger than that of a small diameter portion corresponding to a portion in which the extension portion 33 is not formed.

The ASIC chip 10 and the lead frame 30 may be bonded to each other so that the MEMS sensor 20 bonded to the ASIC chip 10 is received in the through hole 31.

In this case, the lead frame 30 may be electrically connected to the first bump ball 11, such that the ASIC chip 10 may be electrically connected to the lead frame 30 through flip chip bonding.

Thereafter, a molded part 40 may be formed so as to cover the ASIC chip 10, the MEMS sensor 20 and the lead frame 30.

In this case, the mold chip may be formed so that upper surfaces of the ASIC chip 10 and the molded part 40 are positioned on the same plane, such that the upper surface of the ASIC chip 10 may be exposed to the outside of the molded part 40.

The molded part 40 may be formed by a molding method. In this case, at least one of a silicone gel having high thermal conductivity, an epoxy mold compound (EMC), polyimide may be used as a material of the molded part 40.

In this case, the molded part 40 may be filled in the extension portion 33, and the molded part 40 filled in the extension portion 33 may function as a stopper so that the ASIC chip 10 and the MEMS sensor 20 are not separated from the lead frame 30 even in the case in which external impacts, or the like, are applied thereto.

With the manufacturing process of a semiconductor package according to an exemplary embodiment of the present disclosure, the MEMS sensor 20 may be received in the through hole 31 formed in the lead frame 30, a total size of the semiconductor package may be decreased.

In addition, a separate bonding wire process is not required, and the ASIC chip 10, the MEMS sensor 20, and the lead frame 30 may be bonded to each other to thereby be electrically connected to each other, such that the manufacturing process may be simplified.

As set forth above, with the semiconductor package and the manufacturing method thereof according to exemplary embodiments of the present disclosure, the total size of the semiconductor package may be decreased, and the manufacturing process may be simplified.

While exemplary embodiments have been shown and described above, it will be apparent to those skilled in the art that modifications and variations could be made without departing from the spirit and scope of the present disclosure as defined by the appended claims.

What is claimed is:

1. A semiconductor package comprising:
an application specific integrated circuit (ASIC) chip including a first bump ball and a second bump ball formed inwardly of the first bump ball;
a micro electro mechanical system (MEMS) sensor electrically connected to the second bump ball;
a lead frame electrically connected to the first bump ball and including a through hole formed therein; and
a molded part covering the ASIC chip, the MEMS sensor, and the lead frame,
wherein the ASIC chip is disposed above the lead frame.

2. The semiconductor package of claim 1, wherein the ASIC chip has a size larger than that of the MEMS sensor.

3. The semiconductor package of claim 1, wherein the second bump ball is formed on one surface of the ASIC chip facing one surface of the MEMS sensor.

4. The semiconductor package of claim 1, wherein the first bump ball is formed on a portion of one surface of the ASIC chip protruding outwardly of the MEMS sensor.

5. The semiconductor package of claim 1, wherein the MEMS sensor is received in the through hole of the lead frame.

6. The semiconductor package of claim 5, wherein the through hole has a size larger than that of the MEMS sensor and smaller than that of the ASIC chip.

7. The semiconductor package of claim 1, wherein upper surfaces of the ASIC chip and the molded part are positioned on the same plane.

8. The semiconductor package of claim 1, wherein an upper surface of the ASIC chip is exposed to the outside of the molded part.

9. The semiconductor package of claim 1, wherein the through hole of the lead frame includes an extension portion formed to have a diameter larger than that of the through hole.

10. The semiconductor package of claim 1, wherein the molded part is formed of any one of a silicone gel, an epoxy molding compound (EMC), and polyimide.

11. A manufacturing method of a semiconductor package, the manufacturing method comprising:
forming a first bump ball and a second bump ball positioned inwardly of the first bump ball on an ASIC chip;
bonding a MEMS sensor to the ASIC chip;
providing a lead frame including a through hole formed therein;
bonding the ASIC chip and the lead frame to each other; and
forming a molded part so as to cover the ASIC chip, the MEMS sensor, and the lead frame.

12. The manufacturing method of claim 11, wherein in the bonding of the ASIC chip and the lead frame, the MEMS sensor is received in the through hole.

13. The manufacturing method of claim 11, wherein the providing of the lead frame including the through hole formed therein includes forming an extension portion in the through hole so as to have a diameter larger than that of the through hole.

14. The manufacturing method of claim. 11, wherein in the forming of the molded part, an upper surface of the ASIC chip is exposed to the outside of the molded part.

15. The manufacturing method of claim 11, wherein in the forming of the molded part, upper surfaces of the ASIC chip and the molded part are positioned on the same plane.
